(19) United States
(12) Patent Application Publication
(10) Pub. No.: US 2025/0214335 A1
(43) Pub. Date: Jul. 3, 2025

(54) LIQUID EJECTION METHOD, LIQUID EJECTION APPARATUS, IMPRINT METHOD, AND IMPRINT APPARATUS

(71) Applicant: CANON KABUSHIKI KAISHA, Tokyo (JP)

(72) Inventor: HIROAKI FURUKAWA, Tochigi (JP)

(21) Appl. No.: 19/000,187

(22) Filed: Dec. 23, 2024

(30) Foreign Application Priority Data
Dec. 27, 2023 (JP) 2023-220657

(51) Int. Cl. B41J 2/045; G03F 7/00; G03F 7/20

(52) U.S. Cl. CPC B41J 2/04525; B41J 2/04573; G03F 7/0002; G03F 7/2018; B41J 2/04581

(57) ABSTRACT

A liquid ejection method includes an ejection step for ejecting liquid from a liquid ejection head to a substrate such that an ejection pattern is formed on the substrate, a step for correcting a control value for a drive unit for each ejection nozzle of the liquid ejection head on the basis of a relation with another ejection nozzle in the ejection step, and a step for performing the ejection step a plurality of times by using the corrected control value while relatively moving the liquid ejection head and the substrate such that a drop pattern constituted by a plurality of the ejection patterns is formed in an ejection region on the substrate. In the ejection step for forming a first ejection pattern, a second ejection pattern different from the first ejection pattern is formed on the substrate.

### BACKGROUND

### Technical Field

The present disclosure relates to a liquid ejection method, a liquid ejection apparatus, an imprint method, and an imprint apparatus.

### Description of the Related Art

As demand for miniaturization of semiconductor devices and MEMS has become stronger, development of imprint technologies in which an uncured resin on a substrate is formed by a mold and a pattern of the resin is formed on the substrate has advanced. By using imprint technology, a nm-order fine structure can be formed on a substrate.

One of imprint technologies is a light curing method. In an imprint method implemented by the light curing method, first, an uncured photocurable resin (imprint material) is supplied onto a substrate (wafer). Next, the resin on the substrate is brought into contact with a mold (press step). Then, light (ultraviolet rays) is applied in the state in which the resin and the mold contact each other (curing step), thereby curing the resin. After the resin is cured, a distance between the substrate and the mold is increased (release step), so that the mold is released from the cured resin and a pattern of the resin is formed on the substrate.

As a method of applying imprint material onto a substrate, there is a method in which an inkjet type liquid ejection apparatus having a plurality of nozzles is used to eject drops of imprint material onto a substrate. In such a liquid ejection apparatus, there is an influence of crosstalk among nozzles that simultaneously eject liquid. This is because pressure generated by a drive unit such as a piezoelectric element for ejecting liquid from a nozzle propagates to another nozzle through liquid, thereby changing the ejection state of the other nozzle.

Japanese Patent Application Publication No. 2020-89875 discloses a technology for reducing crosstalk among nozzles by ejecting liquid while dividing a drop pattern into a plurality of sub patterns.

Even when a drop pattern is divided into a plurality of sub patterns as in Japanese Patent Application Publication No. 2020-89875, if the number of nozzles that simultaneously eject liquid is plural, there is an influence of crosstalk among the nozzles, and hence ejection accuracy of liquid may be lowered. In order to improve the ejection accuracy of liquid, it is desired to correct a control value of a drive unit for ejection from each nozzle in consideration of crosstalk.

However, how the crosstalk affects corresponds to the number of combinations of the presence/absence of ejection of liquid for a plurality of nozzles (2^{N} combinations when liquid ejection head has N nozzles). In order to store correction information for correcting the influence of crosstalk for all combinations of the presence/absence of ejection of nozzles, a large storage area is necessary in a storage device in a control device.

### SUMMARY

Some embodiments of the present disclosure suppress influence of crosstalk among nozzles in a liquid ejection apparatus and a liquid ejection method for ejecting liquid from a plurality of nozzles.

According to an aspect of the present disclosure, a liquid ejection method by a liquid ejection apparatus for ejecting liquid onto a substrate, the liquid ejection apparatus including a liquid ejection head including a plurality of nozzles for ejecting liquid; and a plurality of drive units for generating energy for ejecting liquid from the plurality of nozzles, respectively, the liquid ejection method including: an ejection step for ejecting liquid from the liquid ejection head to the substrate such that an ejection pattern constituted by one or a plurality of drops arranged in a direction, in which the plurality of nozzles are arrayed, is formed on the substrate; a step for correcting a control value for the drive unit for each ejection nozzle, which is a nozzle that performs ejection in accordance with the ejection pattern in the ejection step among the plurality of nozzles, on the basis of a relation with another ejection nozzle in the ejection step; and a step for performing the ejection step a plurality of times by using the control value corrected in the step for correcting while relatively moving the liquid ejection head and the substrate, such that a drop pattern constituted by a plurality of the ejection patterns arranged in a direction of the relative movement is formed in a predetermined ejection region on the substrate, wherein in the ejection step for forming a first ejection pattern on the substrate among the plurality of ejection patterns constituting the drop pattern, a second ejection pattern, which is different from the first ejection pattern, among the plurality of ejection patterns constituting the drop pattern is formed on the substrate.

According to another aspect of the present disclosure, a liquid ejection apparatus, including: a liquid ejection head including a plurality of nozzles for ejecting liquid; a plurality of drive units for generating energy for ejecting liquid from the plurality of nozzles, respectively; a movement unit for moving the liquid ejection head relative to a substrate to which liquid is to be ejected; and a control unit, wherein the control unit is configured to execute: an ejection step for ejecting liquid from the liquid ejection head to the substrate such that an ejection pattern constituted by one or a plurality of drops arranged in a direction, in which the plurality of nozzles are arrayed, is formed on the substrate; a step for correcting a control value for the drive unit for each ejection nozzle, which is a nozzle that performs ejection in accordance with the ejection pattern in the ejection step among the plurality of nozzles, on the basis of a relation with another ejection nozzle in the ejection step; and a step for performing the ejection step a plurality of times by using the control value corrected in the step for correcting while relatively moving the liquid ejection head and the substrate, such that a drop pattern constituted by a plurality of the ejection patterns arranged in a direction of the relative movement is formed in a predetermined ejection region on the substrate, and wherein in the ejection step for forming a first ejection pattern on the substrate among the plurality of ejection patterns constituting the drop pattern, a second ejection pattern, which is different from the first ejection pattern, among the plurality of ejection patterns constituting the drop pattern is formed on the substrate.

Further features of various embodiments of the present disclosure will become apparent from the following description of exemplary embodiments with reference to the attached drawings.

### BRIEF DESCRIPTION OF THE DRAWINGS

FIG. 1 is a schematic diagram illustrating a configuration of a liquid ejection apparatus in an example.

FIG. 2 is a schematic diagram for describing influence of crosstalk.

FIG. 3A and FIG. 3B are diagrams illustrating a liquid ejection head and an ejection pattern and a drop pattern.

FIG. 4 is a flowchart illustrating a liquid ejection method in Example 1.

FIG. 5 is a diagram for describing a calculation example of a crosstalk correction value.

FIG. 6 is a flowchart illustrating a liquid ejection method in Example 2.

FIG. 7 is a flowchart illustrating a liquid ejection method in Example 3.

FIG. 8 is a diagram illustrating a functional block of a liquid ejection apparatus.

FIG. 9 is a diagram illustrating a configuration of an element substrate in an example.

FIG. 10 is a diagram illustrating an example of a control value of a piezoelectric element.

FIG. 11 is a diagram illustrating an example of a drop pattern.

FIG. 12 is a diagram illustrating an example of a drop pattern.

FIG. 13 is a diagram illustrating an example of a drop pattern.

### DESCRIPTION OF THE EMBODIMENTS

Exemplary embodiments of the present disclosure are described in detail below with reference to the accompanying drawings. The embodiments are not intended to limit the subject matter as recited in the claims or the scope of the subject matter. Note that not all the combinations of features described in the embodiments are essential for solutions.

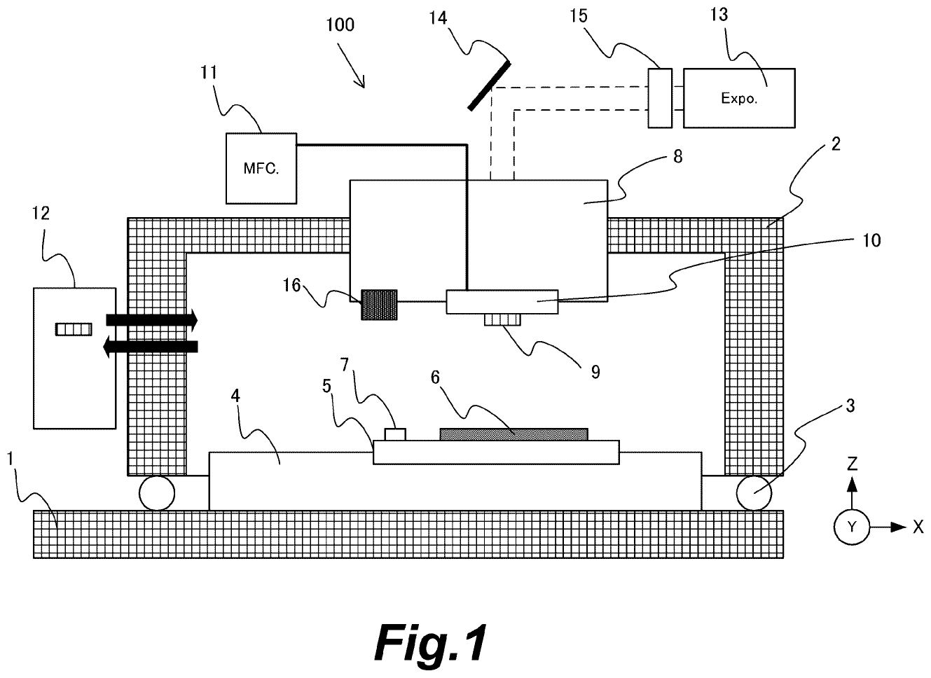

FIG. 1 is a schematic configuration diagram of an imprint apparatus 100 in an example.

The imprint apparatus 100 has a surface plate 1. A substrate stage 5 is provided on the surface plate 1 through a stage drive unit 4 configured by a linear motor or the like. The substrate stage 5 holds a semiconductor wafer (hereinafter sometimes simply referred to as “substrate”) 6, and is movable.

The substrate stage 5 has a built-in distance measurement sensor 7 capable of measuring a distance, and can measure a distance to an opposing object.

The stage drive unit 4 is a movement unit for moving the substrate stage 5 in an illustrated XY direction parallel to the top surface of the surface plate 1. The substrate stage 5 feeds position information detected by means (not shown) such as an interferometer or an encoder back to the stage drive unit 4.

A frame 2 is provided on the surface plate 1 through a damper 3 for canceling vibration from a floor. An imprint module 8 having a Z-drive mechanism unit is mounted to the frame 2.

The imprint module 8 has a mold holding mechanism 10 for holding a mold 9 at a position opposed to the substrate 6. The mold holding mechanism 10 is connected to a gas supply mechanism 11. A freely selected gas can be supplied to the vicinity of the mold 9 through the mold holding mechanism 10.

The mold 9 is loaded and unloaded from and to the outside of the imprint apparatus 100 through a mold transport mechanism 12. The mold transport mechanism 12 has a mechanism for receiving the mold 9 from the outside of the imprint apparatus 100, and has a transport mechanism for transporting the mold 9 to the mold holding mechanism 10 after performing predetermined positioning by a positioning mechanism inside the mold transport mechanism 12.

The mold 9 has a pattern of unevenness formed on its surface opposed to the substrate 6. The imprint module 8 can be vertically driven in a direction (Z direction in FIG. 1) perpendicular to the surface of the substrate 6, and is a pressure unit for pressing the mold 9 against imprint material provided onto the substrate 6. Furthermore, the imprint module 8 is a release unit for releasing the mold 9 from the substrate 6.

In the imprint apparatus 100, in the state in which the substrate 6 is moved relative to a liquid ejection apparatus 16, liquid imprint material (hereinafter sometimes simply referred to as “liquid”) is ejected onto the substrate 6 from the liquid ejection apparatus 16, so that the liquid is applied to the substrate 6. The imprint apparatus 100 has an exposure light source 13 as a curing unit for applying light having a wavelength for curing the imprint material. In the state in which the imprint material applied to the substrate 6 is in a liquid form, the mold holding mechanism 10 is lowered such that the mold 9 is pressed against the substrate 6. After that, light applied from the exposure light source 13 passes through a shutter 15, and is applied to the substrate 6 through a reflection unit 14 and the imprint module 8, thereby curing the imprint material.

After curing, the mold holding mechanism 10 is raised and separated from the substrate 6, and the same pattern of unevenness as the mold 9 is formed on the substrate 6.

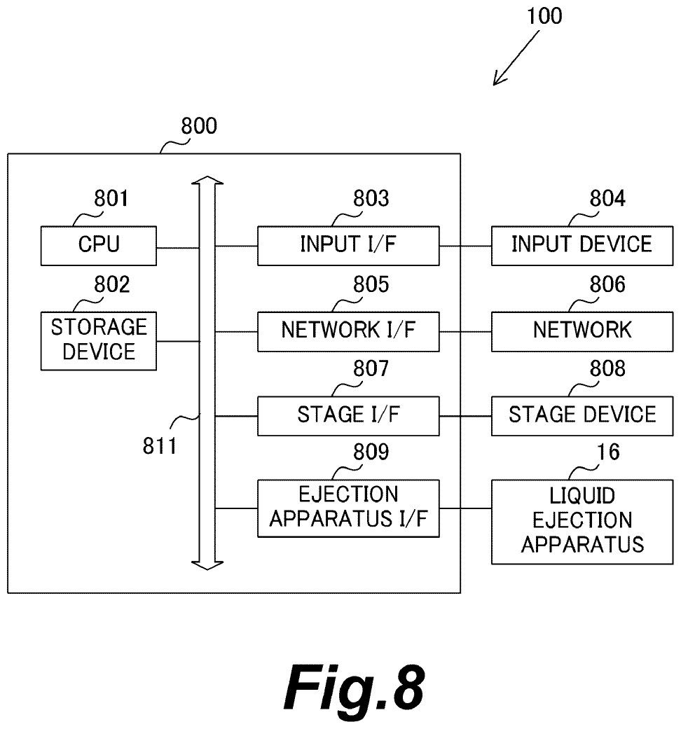

FIG. 8 is a block diagram illustrating a functional configuration and a hardware configuration of the imprint apparatus 100. A control device 800 includes a CPU 801, a storage device 802, an input I/F 803, a network I/F 805, a stage I/F 807, and an ejection apparatus I/F 809, and these components are mutually connected through a bus 811. The bus 811 is configured to transfer data among the components in the control device 800. The CPU 801 executes various commands for controlling the operation of the control device 800. The storage device 802 includes a RAM that functions as a main memory and a work area for the CPU 801, a ROM that stores various programs and data therein, and a fixed disk that stores various setting information and calculation results therein. The input I/F 803 is connected to an input device 804 such as a keyboard. The network I/F 805 is connected to a network 806 such as a local network or the Internet. The stage I/F 807 is connected to various kinds of stage devices 808 related to imprinting, such as the stage drive unit 4, the distance measurement sensor 7, the mold holding mechanism 10, the gas supply mechanism 11, the mold transport mechanism 12, the exposure light source 13, and the shutter 15. The ejection apparatus I/F 809 is connected to the liquid ejection apparatus 16.

The control device 800 controls operation of the stage device 808 and ejection operation of imprint material by the liquid ejection apparatus 16.

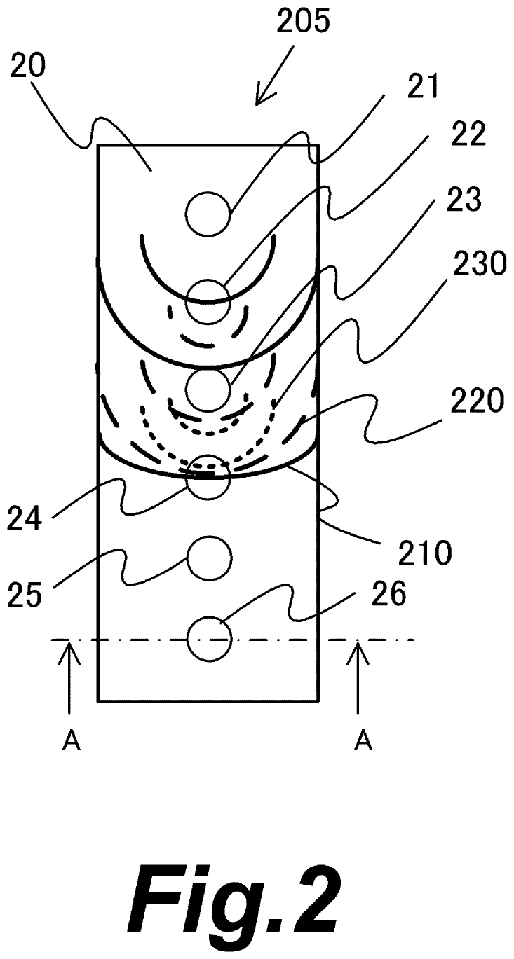

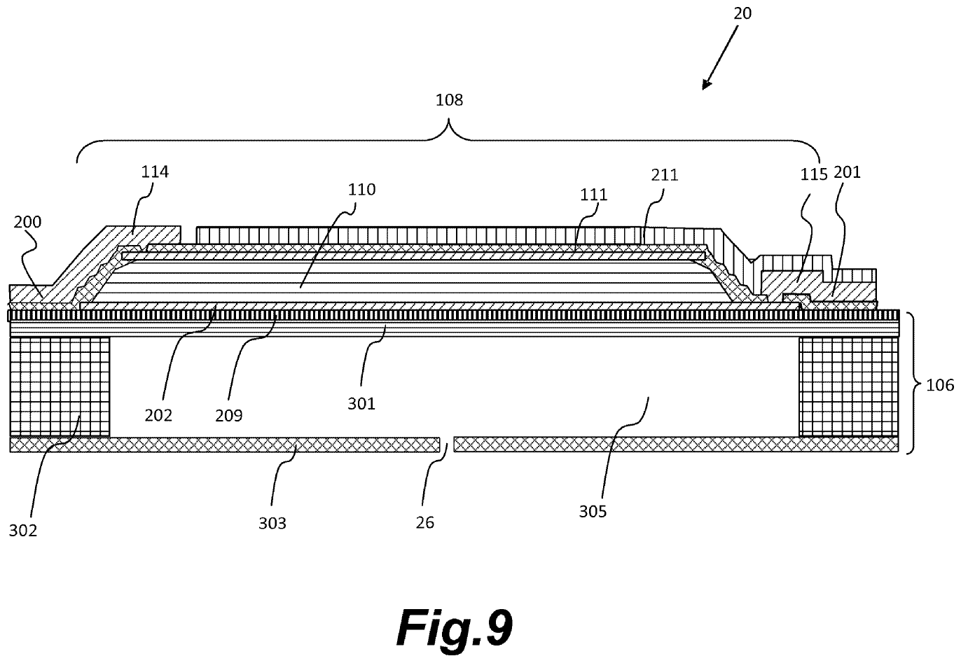

FIG. 2 is a diagram schematically illustrating a liquid ejection head 205 included in the liquid ejection apparatus 16. FIG. 9 is a cross-sectional view of an element substrate 20 included in the liquid ejection head 205, and illustrates the cross section taken along the line AA in FIG. 2.

As illustrated in FIG. 2, the liquid ejection head 205 includes the element substrate 20 having a plurality of nozzles (in the example in FIG. 2, six nozzles 21, 22, 23, 24, 25, and 26) for ejecting liquid. Note that the number of the nozzles is not limited thereto.

As illustrated in FIG. 9, the element substrate 20 included in the liquid ejection head 205 has a piezoelectric element 108 as a drive unit for generating energy used to eject liquid from a nozzle. A base material 106 has an insulating film 209, a vibration plate 301, a flow path forming substrate 302, and a nozzle plate 303. The nozzle 26 is formed in the nozzle plate 303. Liquid (in the example, imprint material or resist material) is ejected from the nozzle 26. The flow path forming substrate 302 is provided on the nozzle plate 303, and the flow path forming substrate 302 partitions a space between the nozzle plate 303 and the vibration plate 301, thereby forming a pressure chamber 305. Note that although not illustrated in FIG. 9 for simplicity, various flow paths for circulating liquid are formed in the flow path forming substrate 302 in addition to the pressure chamber 305. The piezoelectric element 108 is electrically connected to the control device 800 as a control unit through the ejection apparatus I/F 809, and operates on the basis of a drive signal output from the control device 800. The vibration plate 301 deforms depending on the operation of the piezoelectric film 110, and changes internal pressure in the pressure chamber 305, so that liquid is ejected from the nozzle 26.

The piezoelectric element 108 has, on a first surface of the base material 106, a lower electrode 202, a piezoelectric film 110 formed on the top surface of the lower electrode 202, and an upper electrode 111 formed on the top surface of the piezoelectric film 110 in the stated order. Furthermore, the piezoelectric element 108 has an insulating film 211 that covers a part of the top surface of the lower electrode 202 on which the piezoelectric film 110 is not formed, a part of the top surface of the piezoelectric film 110 on which the upper electrode 111 is not formed, the top surface of the upper electrode 111, and the side surfaces of the piezoelectric film 110. The piezoelectric element 108 is provided with signal wiring 200 for supplying an operation signal and common wiring 201 for applying a common potential. An upper electrode pad 114 is disposed at an end of the piezoelectric element 108, and is electrically connected to the signal wiring 200 and the upper electrode 111 of the piezoelectric element 108. Furthermore, an extended region of the lower electrode 202 is provided in the vicinity of an end of the piezoelectric element 108 on the side opposite to the upper electrode pad 114, and a lower electrode pad 115 is disposed on a layer above the extended region. The lower electrode pad 115 is electrically connected to the common wiring 201 and the lower electrode 202.

Referring to FIG. 2, crosstalk among nozzles that occurs when liquid is ejected from the liquid ejection head 205 having a plurality of nozzles is described.

In the case where liquid is simultaneously ejected from a plurality of nozzles, pressure generated from the piezoelectric element 108 for ejecting liquid from each nozzle propagates to another nozzle through the liquid. For example, in FIG. 2, a nozzle 21 to a nozzle 24 are ejection nozzles that perform ejection, and a nozzle 25 and a nozzle 26 are non-ejection nozzles that do not perform ejection. A waveform 210 schematically indicates pressure that propagates from the nozzle 21, a waveform 220 schematically indicates pressure that propagates from the nozzle 22, and a waveform 230 schematically indicates pressure that propagates from the nozzle 23 to the nozzle 24. Thus, the ejection state of the nozzle 24 changes depending on ejection from the nozzles 21 to 23. This is an influence of crosstalk among nozzles.

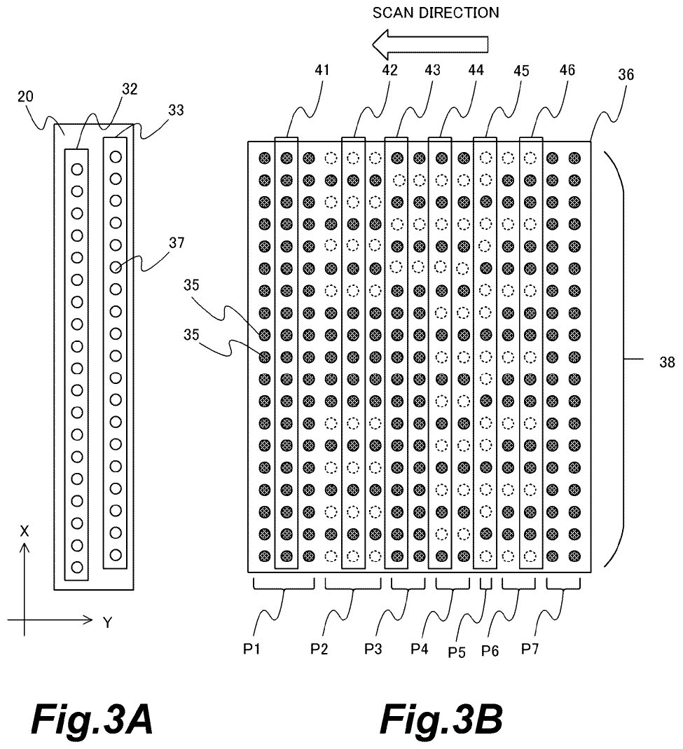

FIG. 3A is a schematic diagram illustrating the element substrate 20 of the liquid ejection head 205. FIG. 3B is a diagram illustrating a drop pattern formed in a predetermined ejection region on a substrate when liquid is ejected from the liquid ejection head 205 to the substrate.

As illustrated in FIG. 3A, the element substrate 20 has a nozzle row 32 and a nozzle row 33. The nozzle row 32 and the nozzle row 33 are disposed side by side along a direction (Y direction) in which the liquid ejection head 205 scans the substrate 6. The nozzle row 32 and the nozzle row 33 each have a plurality of nozzles 37 disposed side by side in the longitudinal direction (X direction) of the element substrate 20. The nozzle row 32 is disposed so as to offset in the X direction with respect to the nozzle row 33 such that positions of the plurality of nozzles 37 in the nozzle row 32 in the X direction and positions of the plurality of nozzles 37 in the nozzle row 33 in the X direction do not overlap each other.

FIG. 3B illustrates a drop pattern formed in a predetermined ejection region 36 on the substrate 6 when liquid is ejected to the substrate 6 from the nozzle row 33. When liquid is ejected to the substrate 6 from the nozzle row 33 of the liquid ejection head 205, an ejection pattern constituted by one or a plurality of drops 35 one-dimensionally arranged in the direction (X direction) in which the plurality of nozzles 37 are arranged is formed on the substrate 6. A step of forming one ejection pattern onto the substrate 6 is referred to as “ejection step”.

By performing the ejection step a plurality of times while the liquid ejection head 205 and the substrate 6 are relatively moved, a drop pattern 38 constituted by a plurality of ejection patterns arranged in the relative movement direction (Y direction) is formed in a predetermined ejection region 36 on the substrate 6. In the example in FIG. 3B, the drop pattern 38 formed in the ejection region 36 is constituted by 15 ejection patterns, and the number of types of the ejection patterns is six (ejection patterns 41, 42, 43, 44, 45, and 46).

How and what type of ejection patterns are disposed in the ejection region 36 are determined depending on the presence/absence and depth of unevenness engraved in the mold 9. In the example in FIG. 3B, the drop pattern 38 is constituted by seven regions P1, P2, P3, P4, P5, P6, and P7 disposed side by side in the Y direction.

The region P1 is formed by three ejection patterns 41. The region P2 is formed by three ejection patterns 42. The region P3 is formed by two ejection patterns 43. The region P4 is formed by two ejection patterns 44. The region P5 is formed by one ejection pattern 45. The region P6 is formed by two ejection patterns 46. The region P7 is formed by two ejection patterns 41.

In a region of the mold 9 corresponding to the region P1, patterns that require a large amount of imprint material are concentrated. Thus, the region P1 is formed by the ejection pattern 41 in which liquid is ejected by all nozzles 37.

In a region of the mold 9 corresponding to the region P2, patterns that require a large amount of imprint material are concentrated near the center. Thus, the region P2 is formed by the ejection pattern 42 in which liquid is ejected by nozzles 37 near the center.

In a region of the mold 9 corresponding to the region P3, patterns that require a large amount of imprint material are concentrated on one side in the X direction (lower side in FIG. 3B). Thus, the region P3 is formed by the ejection pattern 43 in which liquid is ejected by nozzles 37 on one side in the X direction.

In a region of the mold 9 corresponding to the region P4, there is a pattern that does not require a large amount of imprint material. Thus, the region P4 is formed by the ejection pattern 44 in which the number of nozzles 37 for ejection is small.

In a region of the mold 9 corresponding to the region P5, there is a pattern that hardly requires imprint material. Thus, the region P5 is formed by the ejection pattern 45 in which the number of nozzles 37 for ejection is smaller.

In a region of the mold 9 corresponding to the region P6, patterns that require a large amount of imprint material are partially concentrated. Thus, similarly to the region P1, the region P6 is formed by the ejection pattern 46.

In this manner, the drop pattern 38 in the ejection region 36 is determined in accordance with the shape of the mold 9, and hence the thickness of a resist film after imprinting of the mold 9 can be made uniform.

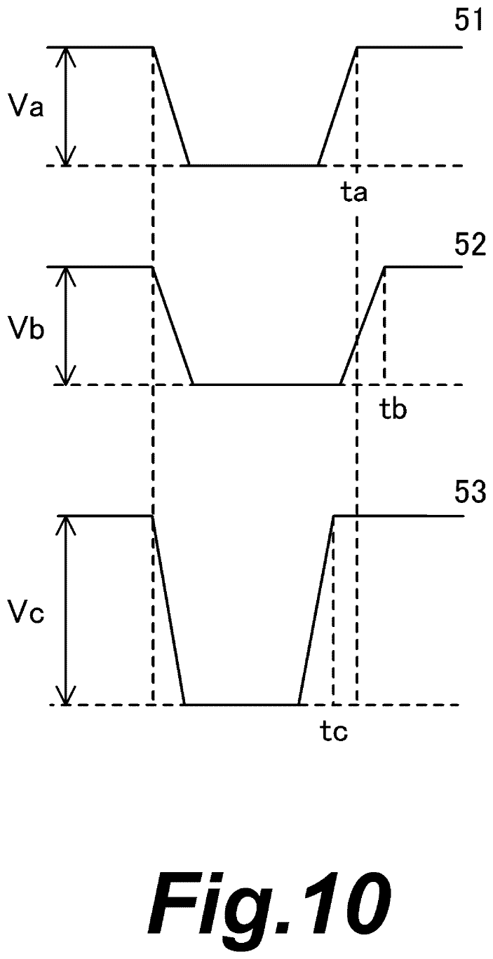

FIG. 10 is a diagram illustrating an example of a drive signal (control value) that is applied to the piezoelectric element 108 in order for the piezoelectric element 108 to generate energy for ejecting liquid from a nozzle 37. As illustrated in FIG. 10, as an example, drive signals 51, 52, and 53 are each a pulse signal to be applied to the piezoelectric element 108 with a predetermined amplitude, pulse length, and timing. By changing amplitudes Va, Vb, and Vc and rising timings ta, tb, and tc of the drive signals 51, 52, and 53, ejection amounts and ejection timings of liquid ejected from nozzles 37 can be changed.

As described above, the plurality of nozzles 37 in the liquid ejection head 205 may include a plurality of ejection nozzles that perform ejection in an ejection step. For example, in each of the ejection steps for forming the ejection patterns 41 to 46 described above, there are a plurality of ejection nozzles. In such a case, the ejection amount and ejection timing from each ejection nozzle may deviate from a target ejection amount and ejection timing due to the influence of crosstalk among ejection nozzles. Thus, by correcting a control value (such as amplitude, pulse length, or timing) of a drive signal for each ejection nozzle on the basis of a relation with another ejection nozzle in an ejection step, the influence of crosstalk can be reduced.

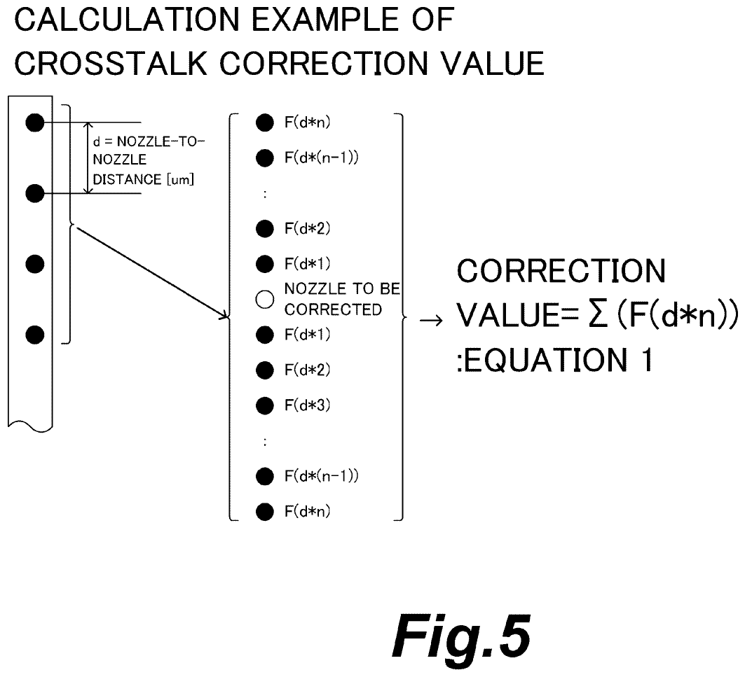

FIG. 5 is a diagram illustrating an example of a method of correcting a control value for an ejection nozzle in order to reduce the influence of crosstalk. In Equation 1 illustrated in FIG. 5, a correction value for correcting an influence of other nozzles on a nozzle to be corrected is calculated on the basis of distances between the nozzle to be corrected and other nozzles. For example, when a distance between adjacent nozzles is indicated by d, a correction value for correcting an influence of another nozzle that is away from a nozzle to be corrected by n nozzles is indicated by a value F(d*n) determined by d*n. Then, the control value for the nozzle to be corrected is corrected by using a value> (F (d*n)) (Equation 1) obtained by summing correction values for all other nozzles.

In a step of forming the drop pattern 38 on the substrate 6 while moving the liquid ejection head 205 relative to the substrate 6, an ejection step for forming each ejection pattern is performed by using the corrected control value. In this manner, an ejection pattern in which the influence of crosstalk has been reduced can be formed.

Information on a corrected control value for each nozzle 37 or correction information (for example, correction value calculated by Equation 1) used for correction of a control value for each nozzle 37 is stored in the storage device 802 as a storage unit in the control device 800. Then, in an ejection step, the corrected control value acquired from the storage device 802 is used or a control value corrected on the basis of the correction information acquired from the storage device 802 is used to drive a piezoelectric element 108 corresponding to each nozzle 37.

In this case, when the number of nozzles 37 constituting the nozzle row 33 in FIG. 3A is N, the number of types of ejection patterns is 2^{N} at a maximum, which is enormous. Then, information on a corrected control value or correction information (hereinafter sometimes simply referred to as “correction information”) for reducing the influence of crosstalk among ejection nozzles is different depending on ejection patterns. Thus, if correction information for all ejection patterns constituting the drop pattern 38 is stored in the storage device 802, a large storage area is necessary in the storage device 802 depending on the number of types of ejection patterns. Furthermore, time required for transferring correction information increases, and throughput of the apparatus may decrease.

Accordingly, in the example, in an ejection step for forming a first ejection pattern on the substrate 6 among a plurality of ejection patterns constituting the drop pattern 38, instead of the first ejection pattern, a second ejection pattern different from the first ejection pattern is formed on the substrate 6. In other words, in the drop pattern 38, the first ejection pattern is replaced with the second ejection pattern. Note that an ejection pattern to be replaced may be one type or a plurality of types. Specifically, in an ejection step for forming a part of a plurality of ejection patterns constituting the drop pattern 38 on the substrate 6, instead of the part of the ejection patterns, a different ejection pattern may be formed on the substrate 6.

Then, correction information corresponding to the first ejection pattern is not stored in the storage device 802. In this manner, correction information to be stored in the storage device 802 can be reduced, and hence a storage area necessary for the storage device 802 can be reduced and time required for transferring correction information can be reduced to improve the throughput of the apparatus.

For example, when the drop pattern 38 is constituted by the ejection pattern 41 to the ejection pattern 46 as in FIG. 3B, by replacing the ejection pattern 45 with the ejection pattern 44, sufficient correction information is only for five types. Furthermore, by replacing the ejection pattern 44 to the ejection pattern 46 with the ejection pattern 41, sufficient correction information is only for three types.

Some specific examples of a method of replacing ejection patterns are described below. Note that the methods of replacing ejection patterns described below are for illustrative purposes, and the replacement methods are not limited thereto.

### Example 1

In Example 1, among a plurality of ejection patterns constituting the drop pattern 38, an ejection pattern whose number of occurrences in the drop pattern 38 is the smallest is replaced with an ejection pattern whose number of occurrences is the largest.

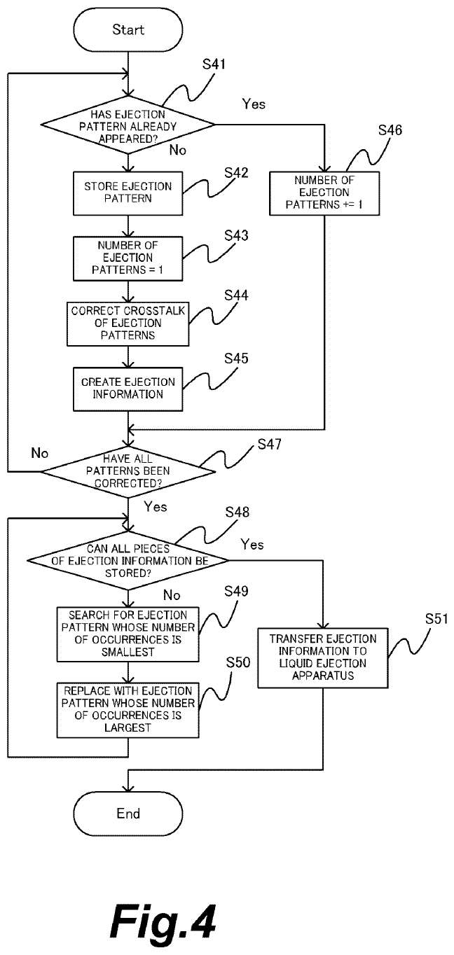

FIG. 4 is a flowchart illustrating processing of crosstalk correction in Example 1. The processing in the flowchart is executed by the control device 800.

In Step S41 to Step S47, the control device 800 performs crosstalk correction for the count of the number of occurrences and the control value for each ejection pattern constituting the drop pattern 38 to be formed in the ejection region 36.

First, in Step S41, the control device 800 determines whether an ejection pattern to be determined is an ejection pattern that has already been subjected to the crosstalk correction. For example, the control device 800 determines the types of ejection patterns from an ejection pattern located at one end in a scan direction (Y direction) of the liquid ejection head 205 to that located at the other end. When the ejection pattern to be determined is an ejection pattern that has already been subjected to the crosstalk correction (an ejection pattern that has already appeared in the drop pattern 38) (Yes in Step S41), the control device 800 executes Step S46. When the ejection pattern to be determined is an ejection pattern that has not been subjected to the crosstalk correction (an ejection pattern that has appeared in the drop pattern 38 for the first time) (No in Step S41), the control device 800 executes Step S42.

In Step S42, the control device 800 stores information on the ejection pattern to be determined (information on presence/absence of ejection for each nozzle 37, control value, and the like) in the storage device 802.

In Step S43, the control device 800 sets the count of the number of occurrences of the ejection pattern to be determined to 1.

In Step S44, the control device 800 calculates, on the basis of the information on the ejection pattern stored in Step S42, correction information used for crosstalk correction of a control value of each nozzle 37 for forming the ejection pattern to be determined (for example, Equation 1 in FIG. 5).

In Step S45, the control device 800 calculates ejection information that is information on the control value of each nozzle 37 for forming the ejection pattern to be determined. The control device 800 calculates the ejection information by correcting a default control value corresponding to the ejection pattern to be determined by using the correction information calculated in Step S44.

In Step S46, the control device 800 adds 1 to the count of the number of occurrences of the ejection pattern to be determined.

In Step S47, the control device 800 determines whether the crosstalk correction has been performed on all ejection patterns constituting the drop pattern 38. When the crosstalk correction has been finished for all ejection patterns constituting the drop pattern 38 (Yes in Step S47), the control device 800 executes Step S48. On the other hand, when there remains an ejection pattern that has not been subjected to the crosstalk correction (No in Step S47), the control device 800 returns to Step S41.

In Step S48, the control device 800 determines whether the storage device 802 has an area for storing ejection information on all ejection patterns constituting the drop pattern 38. When the storage device 802 has an area capable of storing all pieces of ejection information (Yes in Step S48), the control device 800 executes Step S51. When the storage device 802 does not have an area capable of storing all pieces of ejection information (No in Step S48), the control device 800 executes Step S49.

In Step S49, the control device 800 searches for an ejection pattern whose number of occurrences in the drop pattern 38 is the smallest among a plurality of ejection patterns constituting the drop pattern 38.

In Step S50, the control device 800 searches for an ejection pattern whose number of occurrences in the drop pattern 38 is the largest among the plurality of ejection patterns constituting the drop pattern 38. Then, the control device 800 replaces the ejection pattern whose number of occurrences in the drop pattern 38 is the smallest with the ejection pattern whose number of occurrences is the largest. Subsequently, the control device 800 executes Step S48 again.

In Step S51, the control device 800 transfers the ejection information to the liquid ejection apparatus 16.

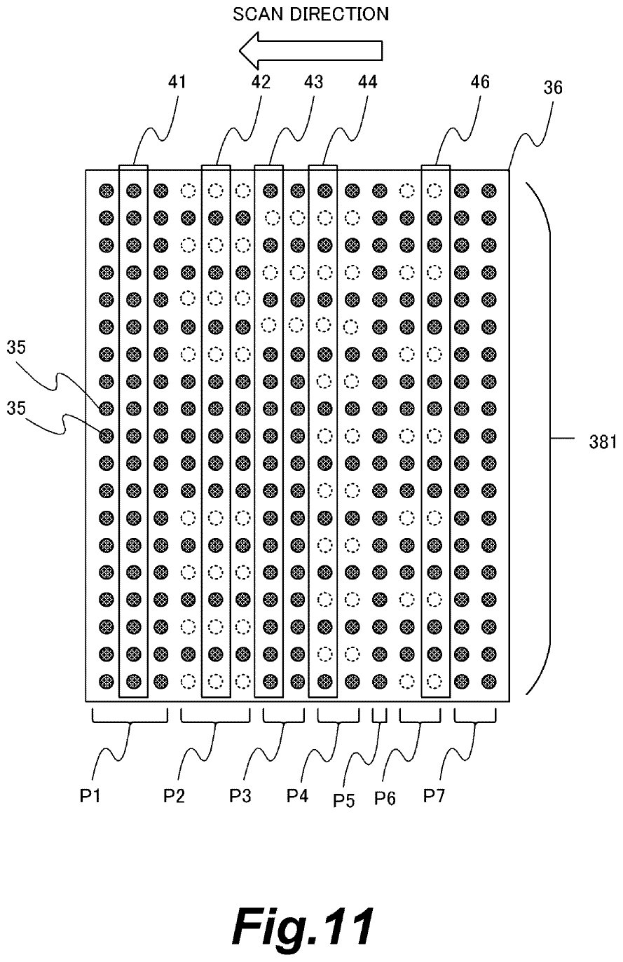

In the case where the above-mentioned processing is applied to the drop pattern 38 illustrated in FIG. 3B, an ejection pattern whose number of occurrences is the smallest is the ejection pattern 45 whose number of occurrences is 1, and an ejection pattern whose number of occurrences is the largest is the ejection pattern 41 whose number of occurrences is 5. Thus, the ejection pattern 45 is replaced with the ejection pattern 41, and a drop pattern 381 after change is as illustrated in FIG. 11. In this manner, ejection information to be stored in the storage device 802 has five types of the ejection patterns 41, 42, 43, 44, and 46, and hence the storage area necessary for storing the ejection information in the storage device 802 can be reduced. Furthermore, the volume of data on ejection information to be transferred to the liquid ejection apparatus 16 is reduced, and hence time required for data transfer can be reduced to improve throughput of the liquid ejection apparatus 16.

Note that, in the above-mentioned flowchart, an example in which ejection patterns are replaced when the storage device 802 does not have a storage area capable of storing all pieces of ejection information has been described (Step S48), but this processing may be omitted. In other words, even when the storage device 802 has a storage area capable of storing all pieces of ejection information, ejection information may be transferred to the liquid ejection apparatus 16 after an ejection pattern whose number of occurrences is the smallest is replaced with an ejection pattern whose number of occurrences is the largest. In this manner, the volume of data on ejection information is reduced, and hence the effect of improving throughput of the liquid ejection apparatus 16 is obtained.

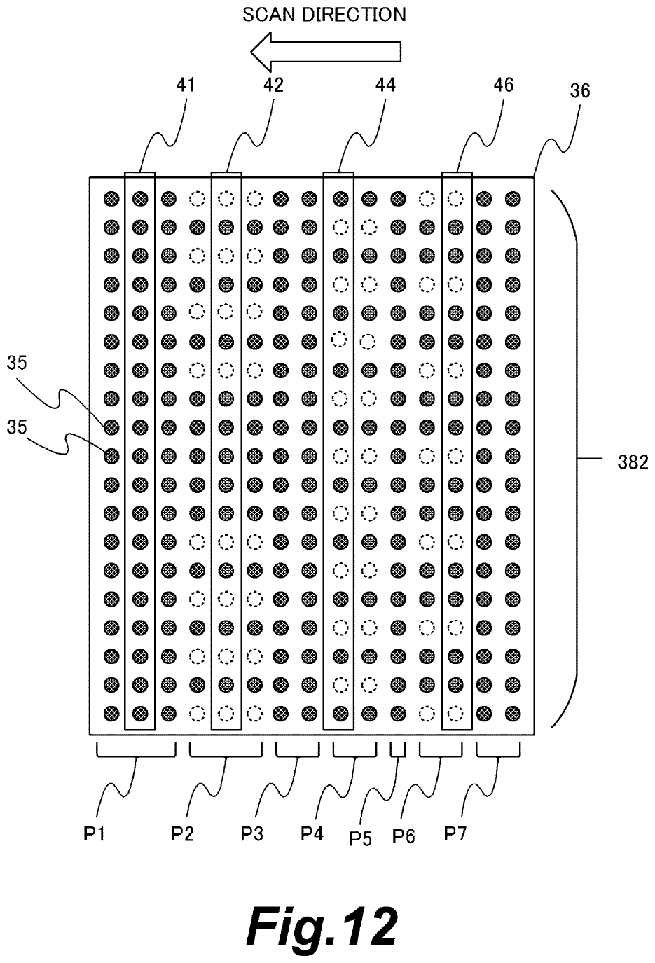

Furthermore, in the above-mentioned flowchart, an example in which the processing for replacing one type of ejection pattern is performed has been described, but the number of types of ejection patterns to be replaced may be plural. For example, in the case where a storage area is still insufficient even after the processing for replacing an ejection pattern whose number of occurrences is the smallest with an ejection pattern whose number of occurrences is the largest is performed once, Step S49 and Step S50 may be executed again for the drop pattern 381 after change. In the case of the drop pattern 381 after change illustrated in FIG. 11, the ejection patterns 43, 44, and 46 are ejection patterns whose numbers of occurrences are the smallest, and the ejection pattern 41 is an ejection pattern whose number of occurrences is the largest. Thus, any one of the ejection patterns 43, 44, and 46 may be replaced with the ejection pattern 41. For example, a drop pattern 382 after change when the ejection pattern 43 has been replaced with the ejection pattern 41 is as illustrated in FIG. 12. In this case, an ejection pattern whose number of occurrences in the original drop pattern 38 is the smallest and an ejection pattern whose number of occurrences is the second smallest have been replaced with an ejection pattern whose number of occurrences is the largest.

Furthermore, also in this case, ejection patterns may be replaced regardless of whether the storage area of the storage device 802 is insufficient.

Furthermore, all ejection patterns other than an ejection pattern whose number of occurrences is the largest among a plurality of ejection patterns constituting the drop pattern 38 may be replaced with the ejection pattern whose number of occurrences is the largest. In this manner, the storage area necessary for storing ejection information in the storage device 802 can be minimized while suppressing a difference between a drop pattern after change by the replacement of ejection patterns and the original drop pattern.

### Example 2

In Example 2, an example in which an ejection pattern located at an end of the ejection region 36 of the substrate 6 among a plurality of ejection patterns constituting the drop pattern 38 is not subject to replacement is described. In other words, an ejection pattern whose number of occurrences in the drop pattern 38 is the smallest among ejection patterns other than an ejection pattern located at an end of the ejection region 36 of the substrate 6 is replaced with an ejection pattern whose number of occurrences is the largest.

A drop pattern is determined on the basis of the density of a pattern of unevenness of the mold 9 such that imprint material does not leak from a mesa. Specifically, an ejection pattern for an edge part of the mesa is set so as to prevent exuding even when a landing error occurs. Thus, if an ejection pattern at an edge part of the mesa is replaced with another ejection pattern, unintended leakage may occur. Accordingly, in a drop pattern, ejection patterns located at ends of the ejection region 36 (ejection patterns at start position and end position of ejection step) are not subject to replacement with another ejection pattern.

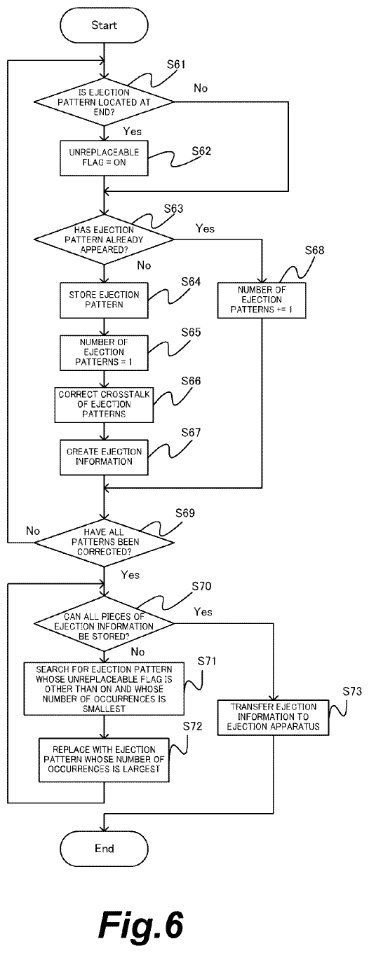

FIG. 6 is a flowchart illustrating processing of crosstalk correction in Example 2. The processing in the flowchart is executed by the control device 800.

In Step S61 to Step S69, the control device 800 performs, for each ejection pattern constituting a drop pattern to be formed in the ejection region 36, the count of number of occurrences, crosstalk correction of the control value, and the setting of an unreplaceable flag.

First, in Step S61, the control device 800 determines whether an ejection pattern to be determined is an ejection pattern located at an end of the ejection region 36. When the ejection pattern to be determined is located at an end of the ejection region 36 (located at start position or end position of ejection step) (Yes in Step S61), the control device 800 executes Step S62. In the other case (No in Step S61), the control device 800 executes Step S63.

In Step S62, the control device 800 sets, for the ejection pattern to be determined, the unreplaceable flag indicating that the ejection pattern is not subject to replacement with another ejection pattern to ON. The default of the unreplaceable flag is OFF, and OFF is set to unreplaceable flags of ejection patterns other than the ejection pattern whose unreplaceable flag has been set to ON.

Processing in Step S63 to Step S70 is the same as the processing in Step S41 to Step S48 in Example 1, and hence detailed descriptions thereof are omitted. In Example 2, when it is determined in Step S70 that there is a storage area capable of storing all pieces of ejection information (Yes in Step S70), the control device 800 executes Step S73. On the other hand, when it is determined that there is no storage area capable of storing all pieces of ejection information (No in Step S70), the control device 800 executes Step S71.

In Step S71, the control device 800 searches for an ejection pattern whose number of occurrences in the drop pattern is the smallest among ejection patterns constituting the drop pattern whose unreplaceable flags are OFF.

In Step S72, the control device 800 searches for an ejection pattern whose number of occurrences in the drop pattern is the largest among the plurality of ejection patterns constituting the drop pattern. Then, the ejection pattern whose number of occurrences is the smallest among the ejection patterns constituting the drop pattern whose unreplaceable flags are OFF is replaced with the ejection pattern whose number of occurrences is the largest. Subsequently, the control device 800 executes Step S70 again.

In Step S73, the control device 800 transfers the ejection information to the liquid ejection apparatus 16.

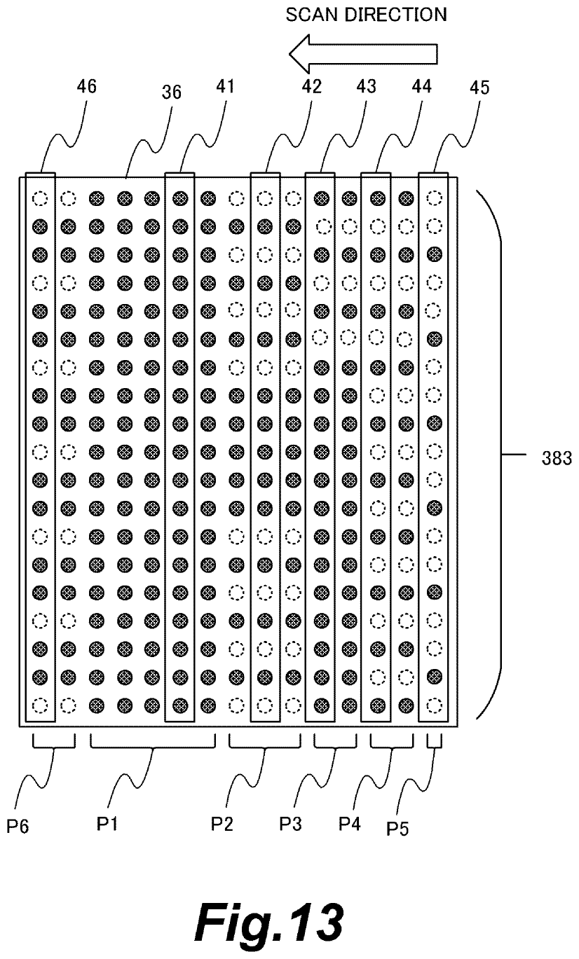

The case where the above-mentioned processing is applied to a drop pattern 383 illustrated in FIG. 13 is described. In the drop pattern 383, unreplaceable flags of an ejection pattern 45 located at one end of the ejection region 36 (located at start position of ejection step) and an ejection pattern 46 located at the other end (located at end position of ejection step) are set to ON. Thus, in Step S72, any one of ejection patterns 43 and 44 whose numbers of occurrences is the smallest among ejection patterns 41, 42, 43, and 44 whose unreplaceable flags are OFF is replaced with the ejection pattern 41 whose number of occurrences is the largest. In this manner, similarly to Example 1, the storage area necessary for storing ejection information in the storage device 802 can be reduced. Furthermore, the volume of data on ejection information to be transferred to the liquid ejection apparatus 16 is reduced, and hence time required for data transfer can be reduced to improve throughput of the liquid ejection apparatus 16. In addition, in Example 2, an ejection pattern located at an end of the ejection region 36 is not replaced, and hence the occurrence of unintended leakage of liquid from a mesa can be suppressed.

### Example 3

In Example 3, an ejection pattern whose number of occurrences in the drop pattern 38 is the smallest among a plurality of ejection patterns constituting the drop pattern 38 is replaced with an ejection pattern in which the number of ejection nozzles is closest to that in the ejection pattern.

In the case of replacing a replacement target ejection pattern (ejection pattern whose number of occurrences is smallest) with another ejection pattern, the ejection pattern is replaced with an ejection pattern in which the number of ejection nozzles is closest to that in the replacement target ejection pattern. Thus, deviation from the original drop pattern can be reduced.

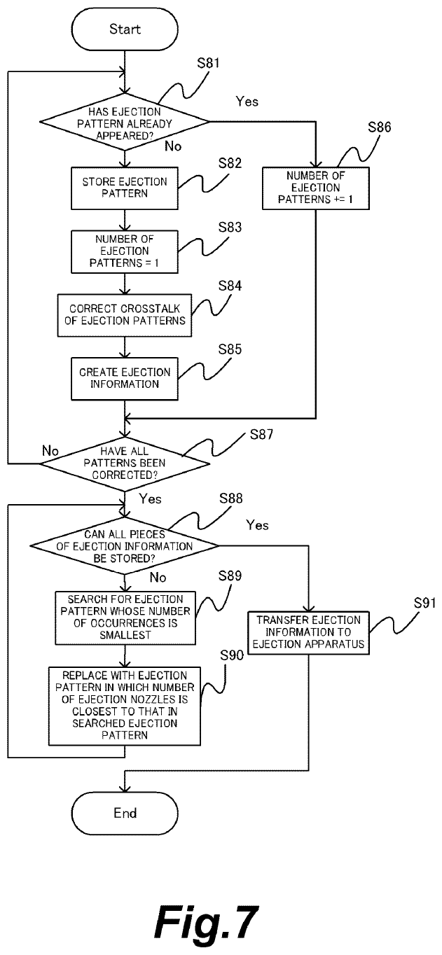

FIG. 7 is a flowchart illustrating processing of crosstalk correction in Example 3. The processing in the flowchart is executed by the control device 800.

Processing in Step S81 to Step S89 and Step S91 is the same as the processing in Step S41 to Step S49 and Step S51 in Example 1, and hence detailed descriptions thereof are omitted.

In Step S90, the control device 800 searches for an ejection pattern (hereinafter sometimes referred to as “approximate pattern”) in which the number of ejection nozzles is closest to that in an ejection pattern whose number of occurrences in the drop pattern 38 is the smallest among a plurality of ejection patterns constituting the drop pattern 38. Then, the ejection pattern whose number of occurrences in the drop pattern 38 is the smallest is replaced with the approximate pattern. Subsequently, the control device 800 executes Step S88 again.

In the case where the above-mentioned processing is applied to the drop pattern 38 illustrated in FIG. 3B, an ejection pattern whose number of occurrences is the smallest is the ejection pattern 45 whose number of occurrences is 1, and the number of ejection nozzles in the ejection pattern 45 is 6. The numbers of ejection nozzles in the other ejection patterns 41, 42, 43, 44, and 46 are 19, 11, 16, 10, and 12, respectively. Thus, the approximate pattern for the ejection pattern 45 whose number of occurrences is the smallest is the ejection pattern 44, and in Step S90, the ejection pattern 45 in the drop pattern 38 is replaced with the ejection pattern 44. In this manner, similarly to Example 1, the storage area necessary for storing ejection information in the storage device 802 can be reduced. Furthermore, the volume of data on ejection information to be transferred to the liquid ejection apparatus 16 is reduced, and hence time required for data transfer can be reduced to improve throughput of the liquid ejection apparatus 16. In addition, in Example 3, a replacement target ejection pattern is replaced with an approximate pattern in which the number of ejection nozzles is close, and hence deviation of a drop pattern to be actually formed in the ejection region 36 from the original drop pattern can be suppressed.

The method of replacing ejection patterns is not limited to the method exemplified in each of the examples described above. For example, in a drop pattern, an ejection pattern that forms at least a part of a region in which the density of drops is low may be replaced with an ejection pattern that forms at least a part of a region in which the density of drops is high. Furthermore, in a drop pattern, an ejection pattern constituting a less important region may be replaced with an ejection pattern constituting a more important region. The number of occurrences and the density of drops in the drop pattern described above can be regarded as an example of an index of importance.

According to the present disclosure, influence of crosstalk among nozzles can be suppressed in a liquid ejection apparatus and a liquid ejection method for ejecting liquid from a plurality of nozzles.

### OTHER EMBODIMENTS

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has described exemplary embodiments, it is to be understood that some embodiments are not limited to the disclosed exemplary embodiments. The scope of the following claims is to be accorded the broadest interpretation so as to encompass all such modifications and equivalent structures and functions.

This application claims priority to Japanese Patent Application No. 2023-220657, which was filed on Dec. 27, 2023 and which is hereby incorporated by reference herein in its entirety.

What is claimed is:

1. A liquid ejection method by a liquid ejection apparatus for ejecting liquid onto a substrate,
the liquid ejection apparatus including:
a liquid ejection head including a plurality of nozzles for ejecting liquid; and
a plurality of drive units for generating energy for ejecting liquid from the plurality of nozzles, respectively,
the liquid ejection method comprising:
an ejection step for ejecting liquid from the liquid ejection head to the substrate such that an ejection pattern constituted by one or a plurality of drops arranged in a direction, in which the plurality of nozzles are arrayed, is formed on the substrate;
a step for correcting a control value for the drive unit for each ejection nozzle, which is a nozzle that performs ejection in accordance with the ejection pattern in the ejection step among the plurality of nozzles, on the basis of a relation with another ejection nozzle in the ejection step; and
a step for performing the ejection step a plurality of times by using the control value corrected in the step for correcting while relatively moving the liquid ejection head and the substrate, such that a drop pattern constituted by a plurality of the ejection patterns arranged in a direction of the relative movement is formed in a predetermined ejection region on the substrate,
wherein in the ejection step for forming a first ejection pattern on the substrate among the plurality of ejection patterns constituting the drop pattern, a second ejection pattern, which is different from the first ejection pattern, among the plurality of ejection patterns constituting the drop pattern is formed on the substrate.

2. The liquid ejection method according to claim 1, wherein the control value is related to an ejection amount and an ejection timing of each of the nozzles.

3. The liquid ejection method according to claim 1, wherein the first ejection pattern is an ejection pattern, the number of occurrences of which in the drop pattern is the smallest among the plurality of ejection patterns constituting the drop pattern.

4. The liquid ejection method according to claim 1, wherein the second ejection pattern is an ejection pattern, the number of occurrences of which in the drop pattern is the largest among the plurality of ejection patterns constituting the drop pattern.

5. The liquid ejection method according to claim 1, wherein the first ejection pattern is an ejection pattern other than an ejection pattern located at an end of the ejection region of the substrate among the plurality of ejection patterns constituting the drop pattern.

6. The liquid ejection method according to claim 1, wherein the second ejection pattern is an ejection pattern in which, the number of nozzles that perform ejection is closest to the number of nozzles that perform ejection in the first ejection pattern among the plurality of ejection patterns constituting the drop pattern.

7. The liquid ejection method according to claim 1, further comprising a step for storing information on the control value, which is corrected in the step for correcting, in a storage unit in the liquid ejection apparatus,
wherein in the ejection step, the plurality of nozzles are driven by using the control value acquired from the storage unit, and
wherein in the step for storing, information on the control value corresponding to the first ejection pattern is not stored in the storage unit.

8. The liquid ejection method according to claim 1, further comprising a step for storing correction information, which is used to correct the control value in the step for correcting, in a storage unit in the liquid ejection apparatus,
wherein in the step for correcting, the control value is corrected by using the correction information acquired from the storage unit, and
wherein in the step for storing, correction information used to correct the control value corresponding to the first ejection pattern is not stored in the storage unit.

9. A liquid ejection method by a liquid ejection apparatus for ejecting liquid onto a substrate,
the liquid ejection apparatus including:
a liquid ejection head including a plurality of nozzles for ejecting liquid; and
a plurality of drive units for generating energy for ejecting liquid from the plurality of nozzles, respectively,
the liquid ejection method comprising:
an ejection step for ejecting liquid from the liquid ejection head to the substrate such that an ejection pattern constituted by one or a plurality of drops arranged in a direction, in which the plurality of nozzles are arrayed, is formed on the substrate;
a step for correcting a control value for the drive unit for each ejection nozzle, which is a nozzle that performs ejection in accordance with the ejection pattern in the ejection step among the plurality of nozzles, on the basis of a relation with another ejection nozzle in the ejection step; and
a step for performing the ejection step a plurality of times by using the control value corrected in the step for correcting while relatively moving the liquid ejection head and the substrate, such that a drop pattern constituted by a plurality of the ejection patterns arranged in a direction of the relative movement is formed in a predetermined ejection region on the substrate,
wherein in the ejection step for forming a part of the plurality of ejection patterns constituting the drop pattern on the substrate, an ejection pattern, which is different from the part of the ejection patterns, among the plurality of ejection patterns constituting the drop pattern is formed on the substrate.

10. The liquid ejection method according to claim 9, wherein the part of the ejection patterns includes a plurality of types of ejection patterns among the plurality of ejection patterns constituting the drop pattern.

11. A liquid ejection apparatus, comprising:
a liquid ejection head including a plurality of nozzles for ejecting liquid;
a plurality of drive units for generating energy for ejecting liquid from the plurality of nozzles, respectively;
a movement unit for moving the liquid ejection head relative to a substrate to which liquid is to be ejected; and
a control unit including one or more memories storing instructions and one or more processors configured to execute:
an ejection step for ejecting liquid from the liquid ejection head to the substrate such that an ejection pattern constituted by one or a plurality of drops arranged in a direction, in which the plurality of nozzles are arrayed, is formed on the substrate;
a step for correcting a control value for the drive unit for each ejection nozzle, which is a nozzle that performs ejection in accordance with the ejection pattern in the ejection step among the plurality of nozzles, on the basis of a relation with another ejection nozzle in the ejection step; and
a step for performing the ejection step a plurality of times by using the control value corrected in the step for correcting while relatively moving the liquid ejection head and the substrate, such that a drop pattern constituted by a plurality of the ejection patterns arranged in a direction of the relative movement is formed in a predetermined ejection region on the substrate,
wherein in the ejection step for forming a first ejection pattern on the substrate among the plurality of ejection patterns constituting the drop pattern, a second ejection pattern, which is different from the first ejection pattern, among the plurality of ejection patterns constituting the drop pattern is formed on the substrate.

12. A liquid ejection apparatus, comprising:
a liquid ejection head including a plurality of nozzles for ejecting liquid;
a plurality of drive units for generating energy for ejecting liquid from the plurality of nozzles, respectively;
a movement unit for moving the liquid ejection head relative to a substrate to which liquid is to be ejected; and
a control unit including one or more memories storing instructions and one or more processors configured to execute:
an ejection step for ejecting liquid from the liquid ejection head to the substrate such that an ejection pattern constituted by one or a plurality of drops arranged in a direction, in which the plurality of nozzles are arrayed, is formed on the substrate;
a step for correcting a control value for the drive unit for each ejection nozzle, which is a nozzle that performs ejection in accordance with the ejection pattern in the ejection step among the plurality of nozzles, on the basis of a relation with another ejection nozzle in the ejection step; and
a step for performing the ejection step a plurality of times by using the control value corrected in the step for correcting while relatively moving the liquid ejection head and the substrate, such that a drop pattern constituted by a plurality of the ejection patterns arranged in a direction of the relative movement is formed in a predetermined ejection region on the substrate,
wherein in the ejection step for forming a part of the plurality of ejection patterns constituting the drop pattern on the substrate, an ejection pattern, which is different from the part of the ejection patterns, among the plurality of ejection patterns constituting the drop pattern is formed on the substrate.

13. An imprint method by a liquid ejection apparatus for ejecting liquid onto a substrate,
the liquid ejection apparatus including:
a liquid ejection head including a plurality of nozzles for ejecting liquid; and
a plurality of drive units for generating energy for ejecting liquid from the plurality of nozzles, respectively,
the imprint method comprising:
an ejection step for ejecting liquid from the liquid ejection head to the substrate such that an ejection pattern constituted by one or a plurality of drops arranged in a direction, in which the plurality of nozzles are arrayed, is formed on the substrate;
a step for correcting a control value for the drive unit for each ejection nozzle, which is a nozzle that performs ejection in accordance with the ejection pattern in the ejection step among the plurality of nozzles, on the basis of a relation with another ejection nozzle in the ejection step;
a step for performing the ejection step a plurality of times by using the control value corrected in the step for correcting while relatively moving the liquid ejection head and the substrate, such that a drop pattern constituted by a plurality of the ejection patterns arranged in a direction of the relative movement is formed in a predetermined ejection region on the substrate,
a step for pressing a surface of a mold having a pattern of unevenness formed thereon against a surface of the substrate on which the drop pattern is formed;
a step for curing the liquid in a state in which the mold is pressed against the substrate; and
a step for releasing the mold from the substrate,
wherein in the ejection step for forming a first ejection pattern on the substrate among the plurality of ejection patterns constituting the drop pattern, a second ejection pattern, which is different from the first ejection pattern, among the plurality of ejection patterns constituting the drop pattern is formed on the substrate.

14. An imprint apparatus, comprising:
a liquid ejection head including a plurality of nozzles for ejecting liquid;
a plurality of drive units for generating energy for ejecting liquid from the plurality of nozzles, respectively;
a movement unit for moving the liquid ejection head relative to a substrate to which liquid is to be ejected; and
a control unit including one or more memories storing instructions and one or more processors configured to execute:
an ejection step for ejecting liquid from the liquid ejection head to the substrate such that an ejection pattern constituted by one or a plurality of drops arranged in a direction, in which the plurality of nozzles are arrayed, is formed on the substrate;
a step for correcting a control value for the drive unit for each ejection nozzle, which is a nozzle that performs ejection in accordance with the ejection pattern in the ejection step among the plurality of nozzles, on the basis of a relation with another ejection nozzle in the ejection step; and
a step for performing the ejection step a plurality of times by using the control value corrected in the step for correcting while relatively moving the liquid ejection head and the substrate, such that a drop pattern constituted by a plurality of the ejection patterns arranged in a direction of the relative movement is formed in a predetermined ejection region on the substrate,
wherein the imprint apparatus further comprises:
a mold having a pattern of unevenness formed thereon;
a pressure unit for pressing a surface, on which the pattern of unevenness is formed, of the mold against a surface of the substrate on which the drop pattern has been formed;
a curing unit for curing the liquid in a state in which the mold is pressed against the substrate; and
a release unit for releasing the mold from the substrate, and
wherein in the ejection step for forming a first ejection pattern on the substrate among the plurality of ejection patterns constituting the drop pattern, a second ejection pattern, which is different from the first ejection pattern, among the plurality of ejection patterns constituting the drop pattern is formed on the substrate.
